(19) United States
(12) Patent Application Publication
(10) Pub. No.: US 2021/0329816 A1
(43) Pub. Date: Oct. 21, 2021

(54) HEAT PIPE WITH LIQUID RESERVOIR

(71) Applicant: Intel Corporation, Santa Clara, CA (US)

(72) Inventors: Gaurav Patankar, Chandler, AZ (US); Ruander Cardenas, Hillsboro, OR (US); Mark Angus MacDonald, Beaverton, OR (US); Jeff Ku, Taipei (TW)

(73) Assignee: Intel Corporation, Santa Clara, CA (US)

(21) Appl. No.: 17/358,271

(22) Filed: Jun. 25, 2021

(51) Int. Cl. H05K 7/20

(52) U.S. Cl. CPC H05K 7/20336; H05K 7/2039

(57) ABSTRACT

Particular embodiments described herein provide for an electronic device that can be configured to include a heat pipe with a liquid reservoir. The heat pipe with a liquid reservoir can include a main heat transfer portion that includes wick material and a vapor channel and a reservoir portion that includes the wick material where the wick material in the reservoir portion occupies at least about fifteen percent more of a volume of the reservoir portion than a percentage of a volume that the wick material occupies in the main heat transfer portion. In an example, the reservoir portion holds surplus liquid that is used when the main heat transfer portion starts to experience dryout.

### TECHNICAL FIELD

This disclosure relates in general to the field of computing and/or device cooling, and more particularly, to a heat pipe with a liquid reservoir.

### BACKGROUND

Emerging trends in electronic devices are changing the expected performance and form factor of devices as devices and systems are expected to increase performance and function while having a relatively thin profile. However, the increase in performance and/or function causes an increase in the thermal challenges of the devices and systems. Insufficient cooling can cause a reduction in device performance, a reduction in the lifetime of a device, and delays in data throughput.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIG. 1A is a simplified block diagram of a system to enable a heat pipe with a liquid reservoir, in accordance with an embodiment of the present disclosure;

FIG. 1B is a simplified block diagram of a system to enable a heat pipe with a liquid reservoir, in accordance with an embodiment of the present disclosure;

FIG. 2A is a simplified block diagram of a partial view of a system to enable a heat pipe with a liquid reservoir, in accordance with an embodiment of the present disclosure;

FIG. 2B is a simplified block diagram of a partial view of a system to enable a heat pipe with a liquid reservoir, in accordance with an embodiment of the present disclosure;

FIG. 3A is a simplified block diagram of a partial view of a system to enable a heat pipe with a liquid reservoir, in accordance with an embodiment of the present disclosure;

FIG. 3B is a simplified block diagram of a partial view of a system to enable a heat pipe with a liquid reservoir, in accordance with an embodiment of the present disclosure;

FIG. 4 is a simplified block diagram of a partial view of a system to enable a heat pipe with a liquid reservoir, in accordance with an embodiment of the present disclosure;

FIGS. 5A-5C is a simplified block diagram of a partial view of the creation of a system to enable a heat pipe with a liquid reservoir, in accordance with an embodiment of the present disclosure;

FIG. 6 is a simplified block diagram of a partial view of a system to enable a heat pipe with a liquid reservoir, in accordance with an embodiment of the present disclosure;

FIG. 7 is a simplified block diagram of a partial view of a heat pipe with a liquid reservoir, in accordance with an embodiment of the present disclosure;

FIG. 8 is a simplified diagram of a partial perspective view of a system to enable a heat pipe with a liquid reservoir, in accordance with an embodiment of the present disclosure;

FIG. 9 is a simplified block diagram view of a system to enable a heat pipe with a liquid reservoir, in accordance with an embodiment of the present disclosure;

FIG. 10 is a simplified block diagram of a partial view of a system to enable a heat pipe with a liquid reservoir, in accordance with an embodiment of the present disclosure;

FIG. 11 is a simplified block diagram of a partial view of a system to enable a heat pipe with a liquid reservoir, in accordance with an embodiment of the present disclosure;

FIG. 12 is a simplified flowchart illustrating potential operations that may be associated with the system in accordance with an embodiment of the present disclosure; and

FIG. 13 is a simplified block diagram of a partial view of a system that includes a heat pipe with a liquid reservoir, in accordance with an embodiment of the present disclosure.

The FIGURES of the drawings are not necessarily drawn to scale, as their dimensions can be varied considerably without departing from the scope of the present disclosure.

### DETAILED DESCRIPTION

### Example Embodiments

The following detailed description sets forth examples of apparatuses, methods, and systems relating to enabling a heat pipe with a liquid reservoir. Features such as structure(s), function(s), and/or characteristic(s), for example, are described with reference to one embodiment as a matter of convenience; various embodiments may be implemented with any suitable one or more of the described features.

In the following description, various aspects of the illustrative implementations will be described using terms commonly employed by those skilled in the art to convey the substance of their work to others skilled in the art. However, it will be apparent to those skilled in the art that the embodiments disclosed herein may be practiced with only some of the described aspects. For purposes of explanation, specific numbers, materials, and configurations are set forth in order to provide a thorough understanding of the illustrative implementations. However, it will be apparent to one skilled in the art that the embodiments disclosed herein may be practiced without the specific details. In other instances, well-known features are omitted or simplified in order not to obscure the illustrative implementations.

The terms “over,” “under,” “below,” “between,” and “on” as used herein refer to a relative position of one layer or component with respect to other layers or components. For example, one layer or component disposed over or under another layer or component may be directly in contact with the other layer or component or may have one or more intervening layers or components. Moreover, one layer or component disposed between two layers or components may be directly in contact with the two layers or components or may have one or more intervening layers or components. In contrast, a first layer or first component “directly on” a second layer or second component is in direct contact with that second layer or second component. Similarly, unless explicitly stated otherwise, one feature disposed between two features may be in direct contact with the adjacent features or may have one or more intervening layers.

In the following detailed description, reference is made to the accompanying drawings that form a part hereof wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). Reference to “one embodiment” or “an embodiment” in the present disclosure means that a particular feature, structure, or characteristic described in connection with the embodiment is included in at least one embodiment. The appearances of the phrase “in one embodiment” or “in an embodiment” are not necessarily all referring to the same embodiment. The appearances of the phrase “for example,” “in an example,” or “in some examples” are not necessarily all referring to the same example.

Furthermore, the term “connected” may be used to describe a direct connection between the things that are connected, without any intermediary devices, while the term “coupled” may be used to describe either a direct connection between the things that are connected, or an indirect connection through one or more intermediary devices. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

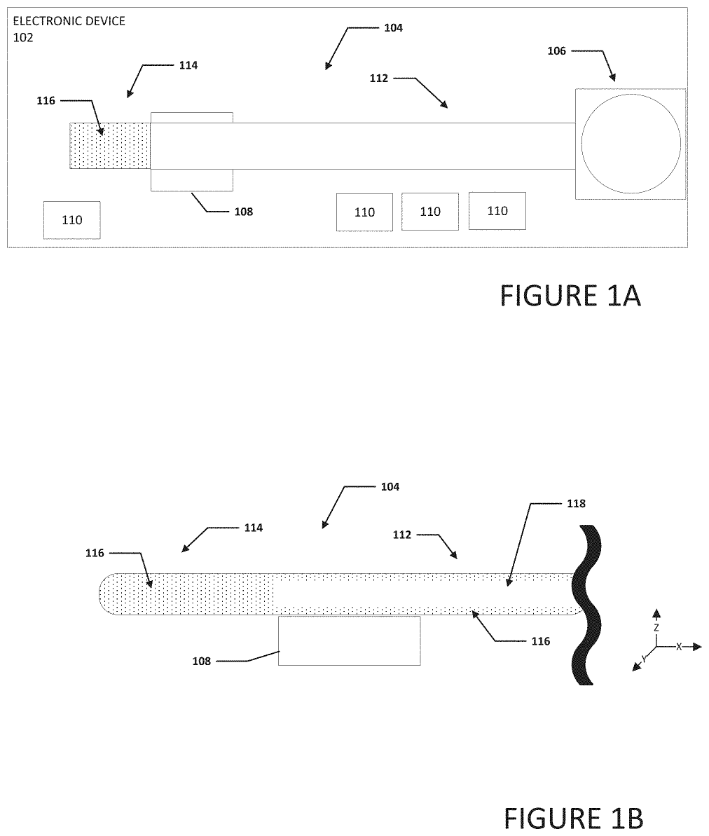

Turning to FIG. 1A, FIG. 1A is a simplified block diagram of an electronic device 102 configured with a heat pipe with a liquid reservoir, in accordance with an embodiment of the present disclosure. In an example, the electronic device 102 can include a heat pipe with a liquid reservoir 104, a heatsink 106, a heat source 108, and one or more electronic components 110. The heat pipe with a liquid reservoir 104 can include a main heat transfer portion 112 and a reservoir portion 114. The heatsink 106 helps to remove the heat collected by the heat pipe with a liquid reservoir 104 and can be an active heatsink or a passive heatsink. The heat source 108 may be a heat generating device (e.g., processor, logic unit, field programmable gate array (FPGA), chip set, integrated circuit (IC), a graphics processor, graphics card, battery, memory, or some other type of heat generating device). Each of the electronic components 110 can be a device or group of devices available to assist in the operation or function of the electronic device 102.

The heat pipe with a liquid reservoir 104 can include a heated end that is over and/or proximate to the heat source 108 and a cooled end that is connected, coupled, near, or proximate to the heatsink 106. The reservoir portion 114 can be located in the heated end of the heat pipe with a liquid reservoir 104, or the end of the heat pipe with a liquid reservoir 104 that is proximate to the heat source 108. At least a majority of the reservoir portion 114 can include wick material 116. The wick material 116 in the reservoir portion 114 can hold surplus liquid to be used as described below. The main heat transfer portion 112 also includes the wick material 116 (not shown in the main heat transfer portion 112) but the amount of the wick material 116 in the main heat transfer portion 112 is less than the amount of the wick material 116 in the reservoir portion 114 to allow vapor to flow in the main heat transfer portion 112 towards the heatsink 106. The wick material 116 can be comprised of sintered powder, metal sintered fibers, screen mesh, grooved or machined walls of the main heat transfer portion 112, metal foam, pins/pillars, or some other material that can allow the condensed liquid phase of the working fluid to flow or be distributed (e.g., from capillary action) from a cooler end of the main heat transfer portion 112 (e.g., near the heatsink 106) to a hotter end of the main heat transfer portion 112 (e.g., near the heat source 108).

Turning to FIG. 1B, FIG. 1B is a simplified block diagram of a portion of the heat pipe with a liquid reservoir 104, in accordance with an embodiment of the present disclosure. In an example, the heat pipe with a liquid reservoir 104 can include the main heat transfer portion 112 and the reservoir portion 114. The reservoir portion 114 can be located in the heated end of the heat pipe with a liquid reservoir 104 or the end of the heat pipe with a liquid reservoir 104 that is proximate to the heat source 108. At least a majority of the reservoir portion 114 can include the wick material 116. The wick material 116 in the reservoir portion 114 can hold surplus liquid to be used as described below. The main heat transfer portion 112 includes the wick material 116 and a vapor channel 118. The amount of the wick material 116 in the main heat transfer portion 112 is less than the amount of the wick material 116 in the reservoir portion 114 to allow vapor to flow through the vapor channel 118 towards the heatsink 106.

The wick material 116 is in an interior volume of the main heat transfer portion 112 and is in an interior volume of the reservoir portion 114. The interior volume of the main heat transfer portion 112 is the space inside the main heat transfer portion 112 that is defined by the outside walls of the main heat transfer portion 112. The interior volume of the reservoir portion 114 is the space inside the reservoir portion 114 that is defined by the outside walls of the reservoir portion 114.

More specifically, the main heat transfer portion 112 is filled with a liquid fluid held by the wick material 116 and vapor (the gas state of the fluid) occupying the vapor channel 118. Heat from the heat source 108 causes the liquid in the wick material 116 to vaporize. The vapor travels along the vapor channel 118 to the heatsink 106 (not shown) or the cold end of the main heat transfer portion 112 and once cooled, the vapor condenses back into a liquid and into the wick material 116. The capillary force in the wick material 116 pulls the liquid back to the portion of the main heat transfer portion 112 over the heat source 108, thus completing the vapor-liquid flow loop. There is a maximum capillary pressure the wick material 116 can provide, defined by its porous structure. The presence of a maximum capillary pressure limits the amount of liquid that can be pulled from the cold end of the main heat transfer portion 112 to the hot end of the main heat transfer portion 112. The power at which the rate of vaporization matches this maximum liquid flow rate is defined as Qₘₐₓ and the phenomenon is commonly defined or known as the capillary limit. In an example, the reservoir portion 114 is away from the heat source such that the fluid in the reservoir portion 114 does not vaporize until the Qₘₐₓ of the main heat transfer portion 112 is reached. In other examples, it can difficult to completely prevent the vaporization of the fluid in the reservoir portion 114 Qₘₐₓ of the main heat transfer portion 112 is reached and at least a portion of the liquid in the reservoir portion 114 may be vaporized before Qₘₐₓ of the main heat transfer portion 112 is reached.

In an illustrative example where the heat pipe with a liquid reservoir 104 switches from a steady operation at a low power to a power above the Qₘₐₓ of the main heat transfer portion 112, the rate of vaporization will exceed the liquid return rate (the amount of liquid that can be pulled from the cold end of the main heat transfer portion 112 to the hot end of the main heat transfer portion 112), which is capped by the capillary limit. This difference in the two rates will deplete the liquid in the main heat transfer portion 112 near the heat source 108 and eventually lead to dryout of the heat pipe with a liquid reservoir 104. The amount of liquid in the main heat transfer portion 112 available near the heat source 108 will determine the time required to reach dryout. The higher the amount of available liquid, the longer it takes before dryout of the heat pipe with a liquid reservoir 104 occurs and the better the heat pipe with a liquid reservoir 104 can perform and help cool the heat source 108.

The heat pipe with a liquid reservoir 104 can use the reservoir portion 114 as an extension of the main heat transfer portion 112 to hold surplus liquid near the heat source 108. This surplus liquid will allow the electronic device 102, or more specifically the heat source 108, to sustain a high-power burst at powers greater than the Qₘₐₓ of the main heat transfer portion 112 without drying out during the burst period. In addition, if the heat source 108 is a processor, the system can allow for increases in the clock frequency of the processor greater than the Qₘₐₓ of the main heat transfer portion 112 for extended durations without experiencing dryout. Note that dryout may still occur or the amount of vapor in the heat pipe with a liquid reservoir 104 may hinder the amount of liquid that can be pulled from the cold end of the main heat transfer portion 112 to the hot end of the main heat transfer portion 112 or even prevent liquid from being pulled from the cold end of the main heat transfer portion 112 to the hot end of the main heat transfer portion 112. However, due to the additional amount of available liquid in the reservoir portion 114, the time to dryout will be longer than if the heat pipe with a liquid reservoir 104 did not include the reservoir portion 114 to store extra liquid.

The system will operate at a power above the Qₘₐₓ of the main heat transfer portion 112 when the system increases in the clock frequency of the processor. A processor's clock frequency represents how many cycles per second the processor can execute. The higher the clock frequency of the processor, the more “switching” can be done per time-unit by the processor. To increase the clock frequency of the processor, the voltage to the processor is increased. As the voltage increases so does the power and the amount of heat that is generated by the heat source. The clock frequency is also referred to as clock speed, clock rate, PC frequency, and CPU frequency, and other similar terms.

As used herein, the term “when” may be used to indicate the temporal nature of an event. For example, the phrase “event ‘A’ occurs when event ‘B’ occurs” is to be interpreted to mean that event A may occur before, during, or after the occurrence of event B, but is nonetheless associated with the occurrence of event B. For example, event A occurs when event B occurs if event A occurs in response to the occurrence of event B or in response to a signal indicating that event B has occurred, is occurring, or will occur. Reference to “one embodiment” or “an embodiment” in the present disclosure means that a particular feature, structure, or characteristic described in connection with the embodiment is included in at least one embodiment. The appearances of the phrase “in one embodiment” or “in an embodiment” are not necessarily all referring to the same embodiment.

It is to be understood that other embodiments may be utilized and structural changes may be made without departing from the scope of the present disclosure. Substantial flexibility is provided in that any suitable arrangements and configuration may be provided without departing from the teachings of the present disclosure.

For purposes of illustrating certain example techniques, the following foundational information may be viewed as a basis from which the present disclosure may be properly explained. End users have more media and communications choices than ever before. A number of prominent technological trends are currently afoot (e.g., more computing elements, more online video services, more Internet traffic, more complex processing, etc.), and these trends are changing the expected performance and form factor of devices as devices and systems are expected to increase performance and function while having a relatively thin profile. However, the increase in performance and/or function causes an increase in the thermal challenges of the devices and systems. For example, in some devices, it can be difficult to cool a particular heat source. One way to cool a heat source is to use a heat pipe.

A heat pipe is a heat-transfer device that combines the principles of both thermal conductivity and phase transition to transfer heat between two interfaces (e.g., a heat source and a heatsink). At the hot interface of a heat pipe (e.g., the portion of the heat pipe near the heat source), a liquid in contact with a thermally conductive solid surface near a heat source turns into a vapor by absorbing heat from that surface. The vapor then travels along the heat pipe to a cold interface (e.g., the heatsink) and condenses back into a liquid, releasing the collected heat. The liquid then returns to the hot interface through either capillary action, centrifugal force, or gravity and the cycle repeats. Due to the very high heat transfer coefficients for boiling and condensation, heat pipes can be highly effective thermal conductors.

A typical heat pipe consists of a sealed pipe or tube made of a material that is compatible with a working fluid (e.g., copper for water heat pipes or aluminum for ammonia heat pipes). During construction of the heat pipe, a vacuum pump is typically used to remove the air from an empty heat pipe. The heat pipe is partially filled with the working fluid and then sealed. The working fluid mass is chosen so that the heat pipe contains both vapor and liquid over a desired operating temperature range. Below the operating temperature, the liquid is cold and cannot vaporize into a gas. Above the operating temperature, all the liquid has turned to gas, and the environmental temperature is too high for any of the gas to condense. Thermal conduction is still possible through the walls of the heat pipe, but at a greatly reduced rate of thermal transfer.

Working fluids are chosen according to the temperatures at which the heat pipe will operate. For example, at extremely low temperature applications, (e.g., about 2-4 K) liquid helium may be used as the fluid and for extremely high temperatures, mercury (e.g., about 523-923 K), sodium (e.g., about 873-1473 K), or indium (e.g., about 2000-3000 K) may be used as the fluid. The vast majority of heat pipes for room temperature applications use water (e.g., about 298-573 K), ammonia (e.g., about 213-373 K), or alcohol (e.g., methanol (e.g., about 283-403 K) or ethanol (e.g., about 273-403 K)) as the fluid. Copper/water heat pipes have a copper envelope, use water as the fluid and typically operate in the temperature range of about twenty degrees Celsius (20° C.) to about one-hundred and fifty degrees Celsius (150° C.). Water heat pipes are sometimes filled by partially filling the heat pipe with water, heating until the water boils and displaces the air, and then sealing the heat pipe while hot.

Heat pipes are ubiquitous in current mobile thermal solutions, however, the maximum cooling capacity (Qₘₐₓ) is still limited, particularly in the thin, aggressive form factors. In some systems, the real workload is bursty, and the system includes high dynamic range silicon to maximize performance and user experience. However, the power supported by the heat pipe is limited due to the maximum cooling capacity Qₘₐₓ of the heat pipe, and hence limits the maximum power of the system. Currently, thermal solutions are chosen such that the combined power limit of multiple heat pipes in the thermal solution exceeds the PL2 power. This is typically achieved by having a relatively large number of heat pipes (e.g., two or more), using large and thicker heat pipes, and/or reducing the clock frequency of the processor. None of those options are appealing to the user because most users want a thin device without compromising the system's performance. What is needed is a system to enable a heat pipe with a liquid reservoir.

A system to enable a heat pipe with a liquid reservoir, as outlined in FIG. 1, can resolve these issues (and others). In an example, a heat pipe with a liquid reservoir (e.g., the heat pipe with a liquid reservoir 104) can be configured to create a surplus reservoir of liquid near the heat input area of an otherwise traditional heat pipe design. The liquid reservoir is an extension of the heat pipe near the heated area that is filled with wick material. The liquid reservoir can be added to a heat pipe by expanding the heat pipe and the size and shape of the liquid reservoir can be based on the available space and design constraints. It is important that the wick filled reservoir be near the heat source such that liquid can efficiently flow to the evaporator region of the heat pipe during high power transients. At the same time, the additional wick material should not be placed right above the heat source to maintain a thin film evaporation layer and effective vapor flow.

In a specific illustrative example, some current mainstream laptops have a first power level of approximately fifteen (15) watts and second power level of approximately fifty (50) watts. The typical thermal solution consists of two heat pipes of 1.5 mm thickness, each with a Qₘₐₓ slightly over twenty-five (25) watts to support the second power level of fifty (50) watts. If a reservoir of ten (10) mm×ten (10) mm×one (1) mm is added, considering the volume and energy of vaporization, the added reservoir it will add about 230 joules of surplus energy per heat pipe. This surplus energy allows the use of thinner pipes that have a Qₘₐₓ that can support the first power level. In some examples, the heat pipe thickness can be reduced from 1.5 mm to less than 1 mm. The difference (50−15=35 watts) can be supported by the surplus energy in the added reservoir for about thirteen (13) seconds. Thus, with the added reservoir, the thickness of mainstream laptops can be reduced by 0.5 mm while still being able to support the second power level for more than ten (10) seconds. As a result, the heat pipe with a liquid reservoir can help to reduce the thickness of heat pipes and/or increase the time spend at second power level.

In an example implementation, the electronic device 102, is meant to encompass a computer, a personal digital assistant (PDA), a laptop or electronic notebook, a cellular telephone, an iPhone, a tablet, an IP phone, network elements, network appliances, servers, routers, switches, gateways, bridges, load balancers, processors, modules, or any other device, component, element, or object that includes a heat source. The electronic device 102 may include any suitable hardware, software, components, modules, or objects that facilitate the operations thereof, as well as suitable interfaces for receiving, transmitting, and/or otherwise communicating data or information in a network environment. This may be inclusive of appropriate algorithms and communication protocols that allow for the effective exchange of data or information. The electronic device 102 may include virtual elements.

In regards to the internal structure, the electronic device 102 can include memory elements for storing information to be used in operations. The electronic device 102 may keep information in any suitable memory element (e.g., random access memory (RAM), read-only memory (ROM), erasable programmable ROM (EPROM), electrically erasable programmable ROM (EEPROM), application specific integrated circuit (ASIC), etc.), software, hardware, firmware, or in any other suitable component, device, element, or object where appropriate and based on particular needs. Any of the memory items discussed herein should be construed as being encompassed within the broad term ‘memory element.’ Moreover, the information being used, tracked, sent, or received could be provided in any database, register, queue, table, cache, control list, or other storage structure, all of which can be referenced at any suitable timeframe. Any such storage options may also be included within the broad term ‘memory element’ as used herein.

In certain example implementations, functions may be implemented by logic encoded in one or more tangible media (e.g., embedded logic provided in an ASIC, digital signal processor (DSP) instructions, software (potentially inclusive of object code and source code) to be executed by a processor, or other similar machine, etc.), which may be inclusive of non-transitory computer-readable media. In some of these instances, memory elements can store data used for operations described herein. This includes the memory elements being able to store software, logic, code, or processor instructions that are executed to carry out activities or operations.

Additionally, the heat source 108 may be or include one or more processors that can execute software or an algorithm. In one example, the processors can transform an element or an article (e.g., data) from one state or thing to another state or thing. In another example, activities may be implemented with fixed logic or programmable logic (e.g., software/computer instructions executed by a processor) and the heat elements identified herein could be some type of a programmable processor, programmable digital logic (e.g., a field programmable gate array (FPGA), an erasable programmable read-only memory (EPROM), an electrically erasable programmable read-only memory (EEPROM)) or an ASIC that includes digital logic, software, code, electronic instructions, or any suitable combination thereof. Any of the potential processing elements, modules, and machines described herein should be construed as being encompassed within the broad term ‘processor.’

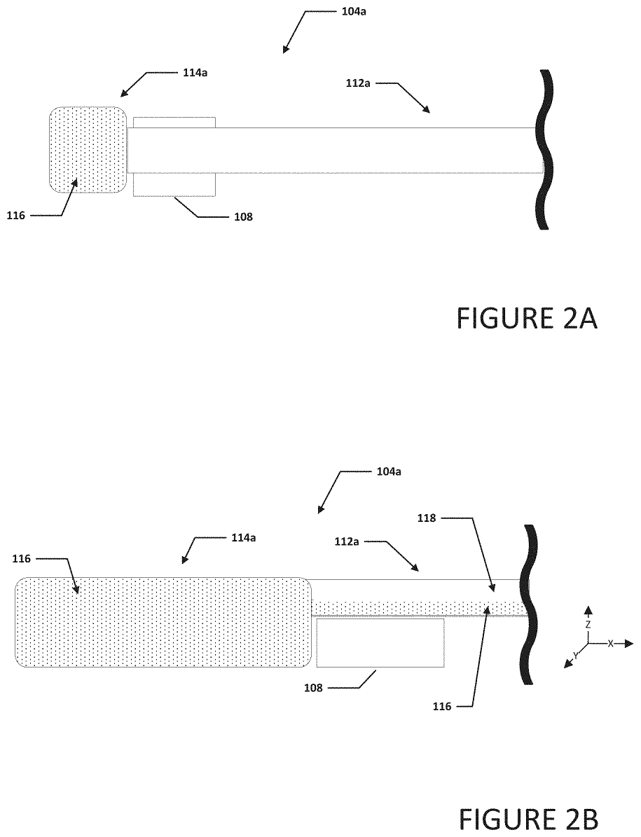

Turning to FIG. 2A, FIG. 2A is a simplified block diagram of a portion of a heat pipe with a liquid reservoir 104a, in accordance with an embodiment of the present disclosure. In an example, the heat pipe with a liquid reservoir 104a can include a main heat transfer portion 112a and a reservoir portion 114a. As illustrated in FIG. 2A, the reservoir portion 114a can have a width that is wider than a width of the main heat transfer portion 112a. The reservoir portion 114a can be located in the heated end of the heat pipe with a liquid reservoir 104a, or the end of the heat pipe with a liquid reservoir 104a that is proximate to the heat source 108. At least a majority of the reservoir portion 114a can include the wick material 116. The wick material 116 in the reservoir portion 114a can hold surplus liquid to be used when needed to help extend the time to dry out of the heat pipe with the liquid reservoir 104a and/or if the heat source is a processor, the amount of time that can be spend using an increased clock frequency of the processor.

Turning to FIG. 2B, FIG. 2B is a simplified block diagram cut away side view of a portion of the heat pipe with a liquid reservoir 104a, in accordance with an embodiment of the present disclosure. In an example, the heat pipe with a liquid reservoir 104a can include the main heat transfer portion 112a and the reservoir portion 114a. As illustrated in FIG. 2B, the reservoir portion 114a can have a height that is greater than a height of the main heat transfer portion 112a. The reservoir portion 114a can be located in the heated end of the heat pipe with a liquid reservoir 104a, or the end of the heat pipe with a liquid reservoir 104a that is proximate to the heat source 108. At least a majority of the reservoir portion 114a can include the wick material 116. The main heat transfer portion 112a includes the wick material 116 and the vapor channel 118. The amount of the wick material 116 in the main heat transfer portion 112a is less than the amount of the wick material 116 in the reservoir portion 114a to allow vapor to flow through the vapor channel 118 towards the heatsink 106 (not shown).

The wick material 116 in the main heat transfer portion 112a can occupy between about thirty percent (30%) of the volume of the main heat transfer portion 112a to about sixty-five (65%) of the volume of the main heat transfer portion 112e and ranges therein (e.g., between about forty percent (40%) and about fifty (50%) of the volume of the main heat transfer portion 112a, or between about forty-five percent (45%) and about sixty (60%) of the volume of the main heat transfer portion 112e), depending on design choice, design constraints, and that amount the wick material 116 in the main heat transfer portion 112a allows for the vapor channel 118 and is less than the amount of wick in the reservoir portion 114a. The wick material 116 in the reservoir portion 114a does not need to be the same type as the wick material 116 in the main heat transfer portion 112a. The amount of wick material 116 in the reservoir portion 114a is greater than the amount of the wick material 116 in the main heat transfer portion 112a. More specifically, the wick material 116 in the reservoir portion 114a can occupy between about sixty-five percent (65%) of the volume in the reservoir portion 114a to about one-hundred percent (100%) of the volume in the reservoir portion 114a and ranges therein (e.g., between about seventy-five percent (75%) and about ninety-five percent (95%) of the volume in the reservoir portion 114a, or between about eighty percent (80%) and about ninety percent (90%) of the volume in the reservoir portion 114a), depending on design choice, design constraints, and that the amount of wick material 116 in the reservoir portion 114a is greater than the amount of wick in the main heat transfer portion 112a. In some examples, the amount of the wick material 116 in the reservoir portion 114a is fifteen percent (15%) or more (e.g., twenty percent (20%), twenty-five percent (25%), thirty percent (30%), etc.) than the amount of the wick material 116 in the main heat transfer portion 112a. More specifically, if the amount of the wick material 116 in the main heat transfer portion 112a is about fifty percent (50%) of the volume of the main heat transfer portion 112a, then the amount of the wick material 116 in the reservoir portion 114a would be about sixty-five percent (65%) or more of the volume of the reservoir portion 114a.

The main heat transfer portion 112a is filled with a fluid held by the wick material 116 and by vapor occupying the vapor channel 118. Heat from the heat source 108 causes the liquid in the wick material 116 to vaporize. The vapor travels along the vapor channel 118 to the heatsink 106 (not shown) or the cold end of the main heat transfer portion 112a and condenses into the wick material 116. The capillary force in the wick material 116 pulls the liquid back the portion of the main heat transfer portion 112a over the heat source 108, thus completing the vapor/liquid flow loop. There is a maximum capillary pressure the wick material 116 can provide, defined by its porous structure. The presence of the maximum capillary pressure limits the amount of liquid that can be pulled from the cold end of the main heat transfer portion 112a to the hot end of the main heat transfer portion 112a. The power at which the rate of vaporization matches this maximum liquid flow rate is defined as Qmax for the main heat transfer portion 112a. The reservoir portion 114a allows the heat pipe with a liquid reservoir 104a to hold surplus liquid to be used when needed to help extend the time to dry out of the main heat transfer portion 112a and/or if the heat source 108 is a processor, the amount of time that can be spend using an increased clock frequency of the processor. This surplus liquid will allow the heat pipe with a liquid reservoir 104a to sustain a high-power burst at powers greater than the Qₘₐₓ of the main heat transfer portion 112a without drying out during the burst period.

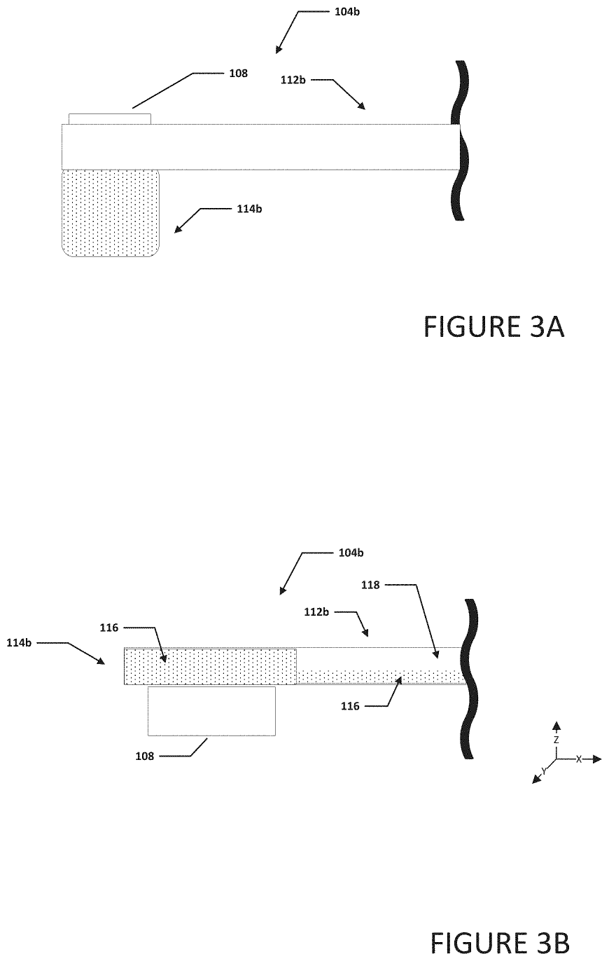

Turning to FIG. 3A, FIG. 3A is a simplified block diagram of a portion of a heat pipe with a liquid reservoir 104b, in accordance with an embodiment of the present disclosure. In an example, the heat pipe with a liquid reservoir 104b can include a main heat transfer portion 112b and a reservoir portion 114b. As illustrated in FIG. 3A, the reservoir portion 114b can be located on a side or end of the main heat transfer portion 112b and have a width that is wider than a width of the main heat transfer portion 112b. The reservoir portion 114b can be located on the heated end of the heat pipe with a liquid reservoir 104b, or the end of the heat pipe with a liquid reservoir 104b that is proximate to the heat source 108. At least a majority of the reservoir portion 114b can include the wick material 116. The wick material 116 in the reservoir portion 114b can hold surplus liquid to be used when needed to help extend the time to dry out of the heat pipe with a liquid reservoir 104b and/or if the heat source 108 is a processor, the amount of time that can be spend using an increased clock frequency of the processor.

Turning to FIG. 3B, FIG. 3B is a simplified block diagram cut away side view of a portion of the heat pipe with a liquid reservoir 104b, in accordance with an embodiment of the present disclosure. In an example, the heat pipe with a liquid reservoir 104b can include the main heat transfer portion 112b and the reservoir portion 114b. At least a majority of the reservoir portion 114b can include the wick material 116. The main heat transfer portion 112b includes the wick material 116 and the vapor channel 118. The amount of the wick material 116 in the main heat transfer portion 112b is less than the amount of the wick material 116 in the reservoir portion 114b to allow vapor to flow through the vapor channel 118 towards the heatsink 106 (not shown).

The wick material 116 in the main heat transfer portion 112b can occupy between about thirty percent (30%) of the volume of the main heat transfer portion 112b to about sixty-five (65%) of the volume of the main heat transfer portion 112b and ranges therein (e.g., between about forty percent (40%) and about fifty (50%) of the volume of the main heat transfer portion 112b, or between about forty-five percent (45%) and about sixty (60%) of the volume of the main heat transfer portion 112b), depending on design choice, design constraints, and that amount the wick material 116 in the main heat transfer portion 112b allows for the vapor channel 118 and is less than the amount of wick in the reservoir portion 114b. The wick material 116 in the reservoir portion 114b does not need to be the same type as the wick material 116 in the main heat transfer portion 112b. The amount of wick material 116 in the reservoir portion 114b is greater than the amount of the wick material 116 in the main heat transfer portion 112b. More specifically, the wick material 116 in the reservoir portion 114b can occupy between about sixty-five percent (65%) of the volume in the reservoir portion 114b to about one-hundred percent (100%) of the volume in the reservoir portion 114b and ranges therein (e.g., between about seventy-five percent (75%) and about ninety-five percent (95%) of the volume in the reservoir portion 114b, or between about eighty percent (80%) and about ninety percent (90%) of the volume in the reservoir portion 114b), depending on design choice, design constraints, and that the amount of wick material 116 in the reservoir portion 114b is greater than the amount of wick in the main heat transfer portion 112b. In some examples, the amount of the wick material 116 in the reservoir portion 114b is fifteen percent (15%) or more (e.g., twenty percent (20%), twenty-five percent (25%), thirty percent (30%), etc.) than the amount of the wick material 116 in the main heat transfer portion 112b. More specifically, if the amount of the wick material 116 in the main heat transfer portion 112b is about fifty percent (50%) of the volume of the main heat transfer portion 112b, then the amount of the wick material 116 in the reservoir portion 114b would be about sixty-five percent (65%) or more of the volume of the reservoir portion 114b.

The main heat transfer portion 112b is filled with a fluid held by the wick material 116 and by vapor occupying the vapor channel 118. Heat from the heat source 108 causes the liquid in the wick material 116 to vaporize. The vapor travels along the vapor channel 118 to the heatsink 106 (not shown) or the cold end of the main heat transfer portion 112b and condenses into the wick material 116. The capillary force in the wick material 116 pulls the liquid back the portion of the main heat transfer portion 112b over the heat source 108, thus completing the vapor-liquid flow loop. There is a maximum capillary pressure the wick material 116 can provide, defined by its porous structure. The presence of a maximum capillary pressure limits the amount of liquid that can be pulled from the cold end of the main heat transfer portion 112b to the hot end of the main heat transfer portion 112b. The power at which the rate of vaporization matches this maximum liquid flow rate is defined as the Qmax for the main heat transfer portion 112b. The reservoir portion 114b allows the heat pipe with a liquid reservoir 104b to hold surplus liquid to be used when needed to help extend the time to dry out of the main heat transfer portion 112b and/or if the heat source 108 is a processor, the amount of time that can be spend using an increased clock frequency of the processor. The surplus liquid will allow the heat pipe with a liquid reservoir 104b to sustain a high-power burst at powers greater than the Qₘₐₓ of the main heat transfer portion 112b.

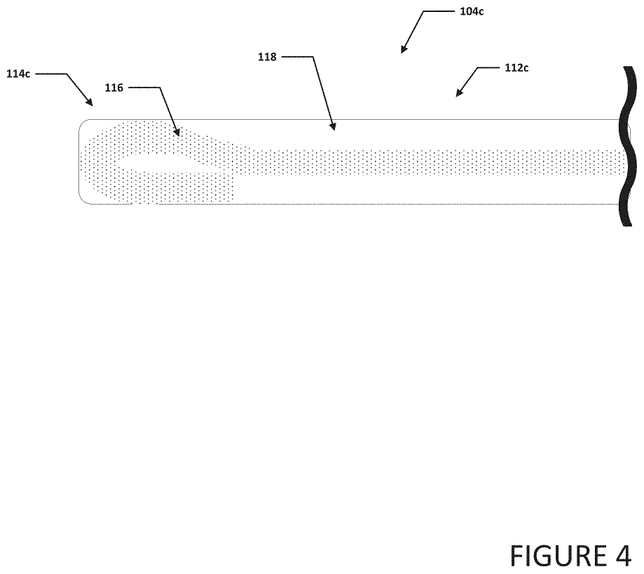

Turning to FIG. 4, FIG. 4 is a simplified block diagram of a portion of a heat pipe with a liquid reservoir 104c, in accordance with an embodiment of the present disclosure. In an example, the heat pipe with a liquid reservoir 104c can include a main heat transfer portion 112c and a reservoir portion 114c. The main heat transfer portion 112c includes the wick material 116 and the vapor channel 118. The amount of the wick material 116 in the main heat transfer portion 112c is less than the amount of the wick material 116 in the reservoir portion 114c to allow vapor to flow through the vapor channel 118 towards the heatsink 106 (not shown). As illustrated in FIG. 4, at least a majority of the reservoir portion 114c can include the wick material 116. The wick material 116 in the reservoir portion 114c can hold surplus liquid to be used when needed. In some examples, the wick material 116 in the reservoir portion 114c can be coiled. In other examples, the wick material 116 in the reservoir portion 114c can be added by some other means of packing, locating, adding etc. the wick material 116 into the reservoir portion 114c.

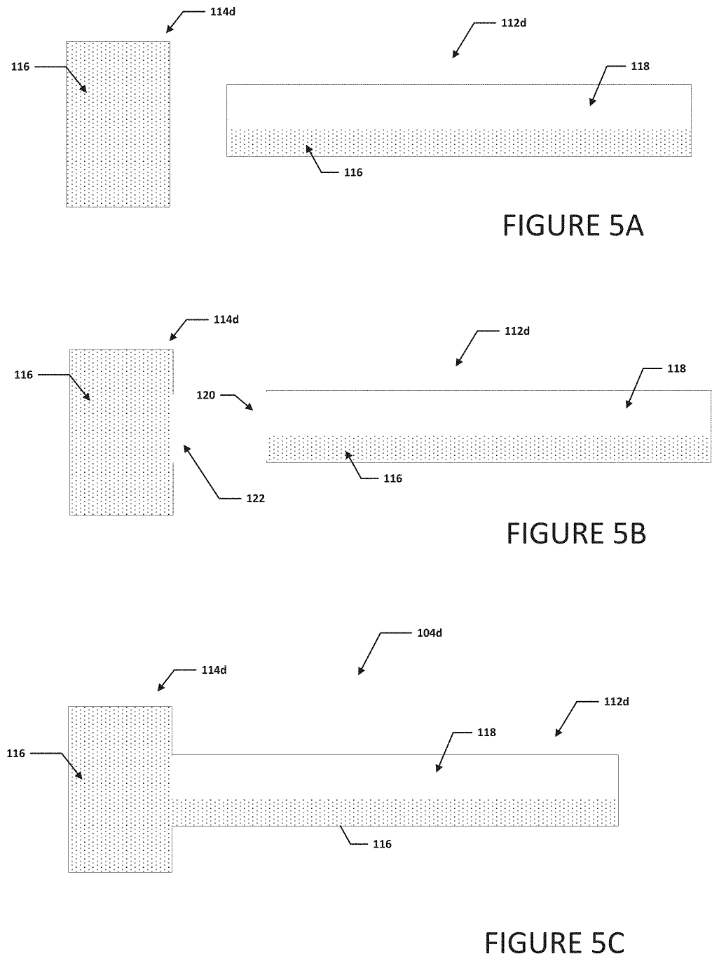

Turning to FIG. 5A, FIG. 5A is a simplified block diagram of a main heat transfer portion 112d and a reservoir portion 114d. In an example, the main heat transfer portion 112d and the reservoir portion 114d can be created or manufactured separately and then joined together to create a heat pipe with a liquid reservoir. At least a majority of the reservoir portion 114d can include the wick material 116. The main heat transfer portion 112d includes the wick material 116 and the vapor channel 118.

Turning to FIG. 5B, FIG. 5B is a simplified block diagram of the main heat transfer portion 112d and the reservoir portion 114d. At least a majority of the reservoir portion 114d can include the wick material 116. The main heat transfer portion 112d includes the wick material 116 and the vapor channel 118. In an example, the main heat transfer portion 112d and the reservoir portion 114d can be created or manufactured separately. As illustrated in FIG. 5B, an opening 120 can be created in the main heat transfer portion 112d to expose the wick material 116 in the main heat transfer portion 112d. In addition, a reservoir opening 122 can be created in the reservoir portion 114d to expose the wick material 116 in the reservoir portion 114d. The size of the reservoir opening 122 is large enough to accommodate the opening 120 in the main heat transfer portion 112d and allow the main heat transfer portion 112d and the reservoir portion 114d to be joined or coupled together to create a heat pipe with a liquid reservoir.

Turning to FIG. 5C, FIG. 5C is a simplified block diagram of a heat pipe with a liquid reservoir 104d. As illustrate in FIG. 5C, the main heat transfer portion 112d has been secured to the reservoir portion 114d to create the heat pipe with a liquid reservoir 104d. The main heat transfer portion 112d can be secured to the reservoir portion 114d by thermal bonding (sintering), brazing, soldering, cold welding, or some other means of securing the main heat transfer portion 112d to the reservoir portion 114d. In an example, the main heat transfer portion 112d and the reservoir portion 114d can be created or manufactured separately at different times and then joined together to create the heat pipe with a liquid reservoir 104d.

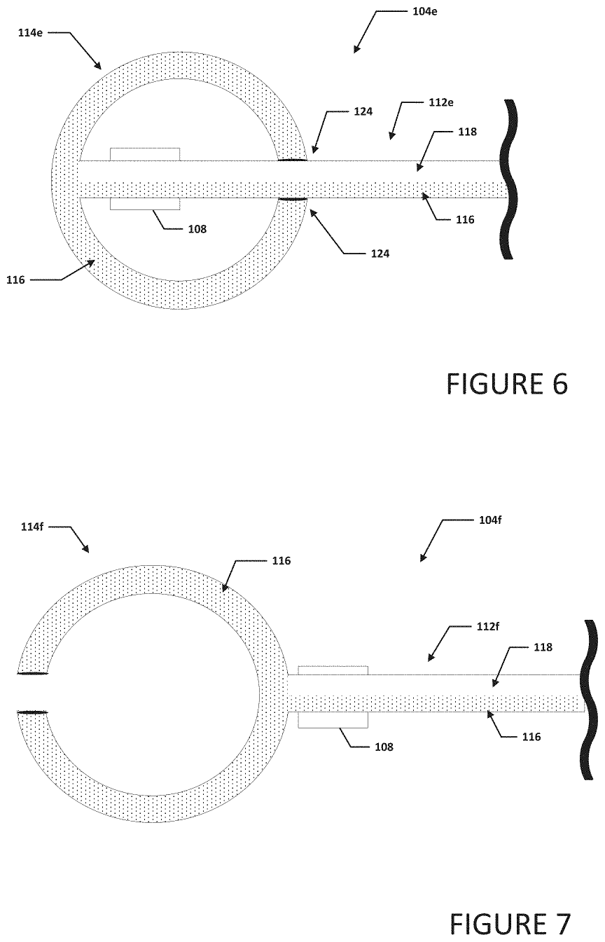

Turning to FIG. 6, FIG. 6 is a simplified block diagram of a portion of a heat pipe with a liquid reservoir 104e, in accordance with an embodiment of the present disclosure. In an example, the heat pipe with a liquid reservoir 104e can include a main heat transfer portion 112e and a reservoir portion 114e. As illustrated in FIG. 6, the reservoir portion 114e can be located on an end of the main heat transfer portion 112e and have a circular profile that extends or circles towards the main heat transfer portion 112e. The ends 124 of the reservoir portion 114e are sealed or closed and not joined to the main heat transfer portion 112e. The reservoir portion 114e can be located in the heated end of the heat pipe with a liquid reservoir 104e, or the end of the heat pipe with a liquid reservoir 104e that is proximate to the heat source 108. At least a majority of the reservoir portion 114e can include the wick material 116. The main heat transfer portion 112e includes the wick material 116 and the vapor channel 118. The amount of the wick material 116 in the main heat transfer portion 112e is less than the amount of the wick material 116 in the reservoir portion 114a to allow vapor to flow through the vapor channel 118 towards the heatsink 106 (not shown).

The wick material 116 in the main heat transfer portion 112e can occupy between about thirty percent (30%) of the volume of the main heat transfer portion 112e to about sixty-five (65%) of the volume of the main heat transfer portion 112e and ranges therein (e.g., between about forty percent (40%) and about fifty (50%) of the volume of the main heat transfer portion 112e, or between about forty-five percent (45%) and about sixty (60%) of the volume of the main heat transfer portion 112e), depending on design choice, design constraints, and that amount the wick material 116 in the main heat transfer portion 112e allows for the vapor channel 118 and is less than the amount of wick in the reservoir portion 114e. The wick material 116 in the reservoir portion 114e does not need to be the same type as the wick material 116 in the main heat transfer portion 112e. The amount of wick material 116 in the reservoir portion 114e is greater than the amount of the wick material 116 in the main heat transfer portion 112e. More specifically, the wick material 116 in the reservoir portion 114e can occupy between about sixty-five percent (65%) of the volume in the reservoir portion 114e to about one-hundred percent (100%) of the volume in the reservoir portion 114e and ranges therein (e.g., between about seventy-five percent (75%) and about ninety-five percent (95%) of the volume in the reservoir portion 114e, or between about eighty percent (80%) and about ninety percent (90%) of the volume in the reservoir portion 114e), depending on design choice, design constraints, and that the amount of wick material 116 in the reservoir portion 114e is greater than the amount of wick in the main heat transfer portion 112e. In some examples, the amount of the wick material 116 in the reservoir portion 114e is fifteen percent (15%) or more (e.g., twenty percent (20%), twenty-five percent (25%), thirty percent (30%), etc.) than the amount of the wick material 116 in the main heat transfer portion 112e. More specifically, if the amount of the wick material 116 in the main heat transfer portion 112e is about fifty percent (50%) of the volume of the main heat transfer portion 112e, then the amount of the wick material 116 in the reservoir portion 114e would be about sixty-five percent (65%) or more of the volume of the reservoir portion 114e.

The main heat transfer portion 112e is filled with a fluid held by the wick material 116 and vapor occupying the vapor channel 118. Heat from the heat source 108 causes the liquid in the wick material 116 to vaporize. The vapor travels along the vapor channel 118 to the heatsink 106 (not shown) or the cold end of the main heat transfer portion 112e and condenses into the wick material 116. The capillary force in the wick material 116 pulls the liquid back the portion of the main heat transfer portion 112e over the heat source 108, thus completing the vapor-liquid flow loop. The reservoir portion 114e allows the heat pipe with a liquid reservoir 104e to hold surplus liquid to be used when needed to help extend the time to dry out of the main heat transfer portion 112e and/or if the heat source 108 is a processor, the amount of time that can be spend using an increased clock frequency of the processor. This surplus liquid will allow the heat pipe with a liquid reservoir 104e to sustain a high-power burst at powers greater than the Qₘₐₓ of the main heat transfer portion 112e.

Turning to FIG. 7, FIG. 7 is a simplified diagram of a portion of a heat pipe with a liquid reservoir 104f, in accordance with an embodiment of the present disclosure. In an example, the heat pipe with a liquid reservoir 104f can include a main heat transfer portion 112f and a reservoir portion 114f. As illustrated in FIG. 7, the reservoir portion 114f can be located on an end of the main heat transfer portion 112f and have a circular profile that extends or circles away the main heat transfer portion 112f. The reservoir portion 114f can be located in the heated end of the heat pipe with a liquid reservoir 104f, or the end of the heat pipe with a liquid reservoir 104f that is proximate to the heat source 108. At least a majority of the reservoir portion 114f can include the wick material 116. The main heat transfer portion 112f includes the wick material 116 and the vapor channel 118. The amount of the wick material 116 in the main heat transfer portion 112e is less than the amount of the wick material 116 in the reservoir portion 114f to allow vapor to flow through the vapor channel 118 towards the heatsink 106.

The wick material 116 in the main heat transfer portion 112f can occupy between about thirty percent (30%) of the volume of the main heat transfer portion 112e to about sixty-five (65%) of the volume of the main heat transfer portion 112f and ranges therein (e.g., between about forty percent (40%) and about fifty (50%) of the volume of the main heat transfer portion 112e, or between about forty-five percent (45%) and about sixty (60%) of the volume of the main heat transfer portion 112f), depending on design choice, design constraints, and that amount the wick material 116 in the main heat transfer portion 112f allows for the vapor channel 118 and is less than the amount of wick in the reservoir portion 114f. The wick material 116 in the reservoir portion 114f does not need to be the same type as the wick material 116 in the main heat transfer portion 112f. The amount of wick material 116 in the reservoir portion 114f is greater than the amount of the wick material 116 in the main heat transfer portion 112f. More specifically, the wick material 116 in the reservoir portion 114f can occupy between about sixty-five percent (65%) of the volume in the reservoir portion 114f to about one-hundred percent (100%) of the volume in the reservoir portion 114f and ranges therein (e.g., between about seventy-five percent (75%) and about ninety-five percent (95%) of the volume in the reservoir portion 114e, or between about eighty percent (80%) and about ninety percent (90%) of the volume in the reservoir portion 114f), depending on design choice, design constraints, and that the amount of wick material 116 in the reservoir portion 114f is greater than the amount of wick in the main heat transfer portion 112f. In some examples, the amount of the wick material 116 in the reservoir portion 114f is fifteen percent (15%) or more (e.g., twenty percent (20%), twenty-five percent (25%), thirty percent (30%), etc.) than the amount of the wick material 116 in the main heat transfer portion 112f. More specifically, if the amount of the wick material 116 in the main heat transfer portion 112f is about fifty percent (50%) of the volume of the main heat transfer portion 112f, then the amount of the wick material 116 in the reservoir portion 114f would be about sixty-five percent (65%) or more of the volume of the reservoir portion 114f.

The main heat transfer portion 112f is filled with a liquid or fluid held by the wick material 116 and vapor occupying the vapor channel 118. Heat from the heat source 108 causes the liquid in the wick material 116 to vaporize. The vapor travels along the vapor channel 118 to the heatsink 106 (not shown) or the cold end of the main heat transfer portion 112f and condenses into the wick material 116. The capillary force in the wick material 116 pulls the liquid back the portion of the main heat transfer portion 112f over the heat source 108, thus completing the vapor-liquid flow loop. The reservoir portion 114f allows the heat pipe with a liquid reservoir 104f to hold surplus liquid to be used when needed to help extend the time to dry out of the main heat transfer portion 112f and/or if the heat source 108 is a processor, the amount of time that can be spend using an increased clock frequency of the processor. This surplus liquid will allow the heat pipe with a liquid reservoir 104f to sustain a high-power burst at powers greater than the Qₘₐₓ of the main heat transfer portion 112f.

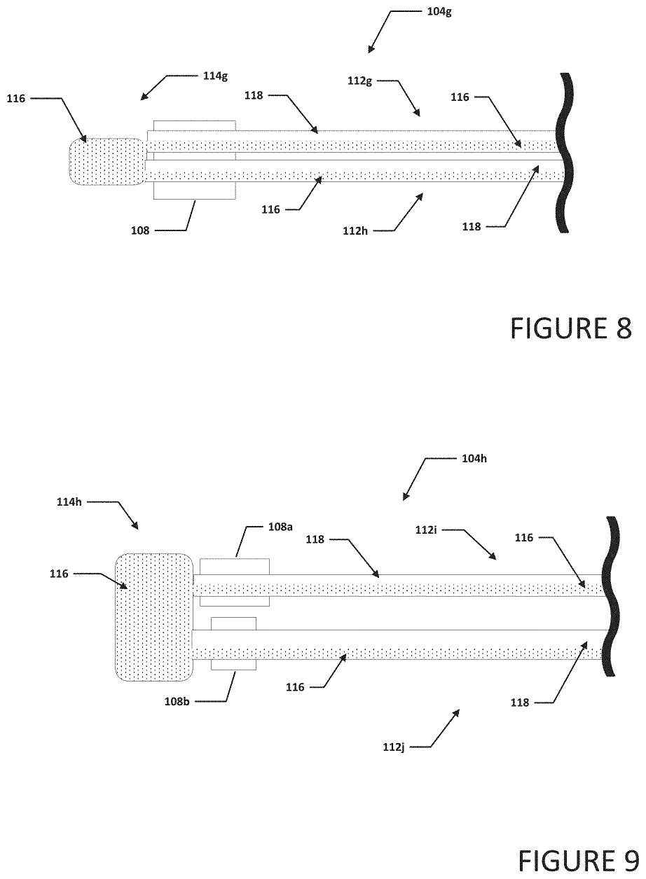

Turning to FIG. 8, FIG. 8 is a simplified block diagram of a portion of a heat pipe with a liquid reservoir 104g, in accordance with an embodiment of the present disclosure. In an example, the heat pipe with a liquid reservoir 104g can include a main heat transfer portion 112g, a main heat transfer portion 112h, and a reservoir portion 114g. As illustrated in FIG. 8, the main heat transfer portion 112g and the main heat transfer portion 112h can both be connected or coupled to the reservoir portion 114g. The reservoir portion 114g can be located on a side or end of the main heat transfer portion 112g and the main heat transfer portion 112h and have a width that is wider than a width of the main heat transfer portion 112g and/or the main heat transfer portion 112h. The reservoir portion 114g can be located on the heated end of the heat pipe with a liquid reservoir 104g, or the end of the heat pipe with a liquid reservoir 104g that is proximate to the heat source 108. At least a majority of the reservoir portion 114g can include the wick material 116. The wick material 116 in the reservoir portion 114g can hold surplus liquid to be used when needed to help extend the time to dry out of the main heat transfer portion 112g and the main heat transfer portion 112h and/or if the heat source 108 is a processor, the amount of time that can be spend using an increased clock frequency of the processor.

The main heat transfer portion 112g and the main heat transfer portion 112h each include the wick material 116 and the vapor channel 118. The amount of the wick material 116 in the main heat transfer portion 112g and the main heat transfer portion 112h is less than the amount of the wick material 116 in the reservoir portion 114g to allow vapor to flow through the vapor channel 118 towards the heatsink 106 (not shown).

The wick material 116 in the main heat transfer portion 112g can occupy between about thirty percent (30%) of the volume of the main heat transfer portion 112g to about sixty-five (65%) of the volume of the main heat transfer portion 112g and ranges therein (e.g., between about forty percent (40%) and about fifty (50%) of the volume of the main heat transfer portion 112g, or between about forty-five percent (45%) and about sixty (60%) of the volume of the main heat transfer portion 112g), depending on design choice, design constraints, and that amount the wick material 116 in the main heat transfer portion 112g allows for the vapor channel 118 and is less than the amount of wick in the reservoir portion 114g. The wick material 116 in the main heat transfer portion 112h can occupy between about thirty percent (30%) of the volume of the main heat transfer portion 112h to about sixty-five (65%) of the volume of the main heat transfer portion 112h and ranges therein (e.g., between about forty percent (40%) and about fifty (50%) of the volume of the main heat transfer portion 112h, or between about forty-five percent (45%) and about sixty (60%) of the volume of the main heat transfer portion 112h), depending on design choice, design constraints, and that amount the wick material 116 in the main heat transfer portion 112h allows for the vapor channel 118 and is less than the amount of wick in the reservoir portion 114g. The amount of the wick material 116 in the main heat transfer portion 112g and in the main heat transfer portion 112h does not need to be the same amount of wick material 116. The wick material 116 in the reservoir portion 114g does not need to be the same type as the wick material 116 in the main heat transfer portion 112g or 112h. The amount of wick material 116 in the reservoir portion 114g is greater than the amount of the wick material 116 in the main heat transfer portion 112g and the main heat transfer portion 112h. More specifically, the wick material 116 in the reservoir portion 114g can occupy between about sixty-five percent (65%) of the volume in the reservoir portion 114g to about one-hundred percent (100%) of the volume in the reservoir portion 114g and ranges therein (e.g., between about seventy-five percent (75%) and about ninety-five percent (95%) of the volume in the reservoir portion 114g, or between about eighty percent (80%) and about ninety percent (90%) of the volume in the reservoir portion 114g), depending on design choice, design constraints, and that the amount of wick material 116 in the reservoir portion 114g is greater than the amount of wick in the main heat transfer portion 112g and the main heat transfer portion 112h. In some examples, the amount of the wick material 116 in the reservoir portion 114g is fifteen percent (15%) or more (e.g., twenty percent (20%), twenty-five percent (25%), thirty percent (30%), etc.) than the amount of the wick material 116 in the main heat transfer portion 112g or the main heat transfer portion 112h. More specifically, if the amount of the wick material 116 in the main heat transfer portion 112g is about fifty percent (50%) of the volume of the main heat transfer portion 112g or the amount of the wick material 116 in the main heat transfer portion 112h is about fifty percent (50%) of the volume of the main heat transfer portion 112g, then the amount of the wick material 116 in the reservoir portion 114g would be about sixty-five percent (65%) or more of the volume of the reservoir portion 114g.

The main heat transfer portion 112g and the main heat transfer portion 112h are each filled with a fluid held by the wick material 116 and vapor occupying the vapor channel 118. Heat from the heat source 108 causes the liquid in the wick material 116 to vaporize. The vapor travels along the vapor channel 118 to the heatsink 106 (not shown) or the cold end of the main heat transfer portion 112g and the main heat transfer portion 112h and condenses into the wick material 116. The capillary force in the wick material 116 pulls the liquid back to the portion of the main heat transfer portion 112g and the main heat transfer portion 112h over the heat source 108, thus completing the vapor-liquid flow loop. There is a maximum capillary pressure the wick material 116 can provide, defined by its porous structure. The presence of a maximum capillary pressure limits the amount of liquid that can be pulled from the cold end of the main heat transfer portion 112g and the main heat transfer portion 112h to the hot end of the main heat transfer portion 112g and the main heat transfer portion 112h. The reservoir portion 114g allows the heat pipe with a liquid reservoir 104g to hold surplus liquid to be used when needed to help extend the time to dry out of the main heat transfer portion 112g and the main heat transfer portion 112h and/or if the heat source 108 is a processor, the amount of time that can be spend using an increased clock frequency of the processor. This surplus liquid will allow the heat pipe with a liquid reservoir 104g to sustain a high-power burst at powers greater than the Qₘₐₓ of the main heat transfer portion 112g and/or the main heat transfer portion 112h.

Turning to FIG. 9, FIG. 9 is a simplified diagram of is a simplified block diagram of a portion of a heat pipe with a liquid reservoir 104h, in accordance with an embodiment of the present disclosure. In an example, the heat pipe with a liquid reservoir 104h can include a main heat transfer portion 112i, a main heat transfer portion 112j, and a reservoir portion 114h. The heat pipe with a liquid reservoir 104h can be over one or more heat sources. For example, as illustrated in FIG. 9, the heat pipe with a liquid reservoir 104h can be over the first heat source 108a and the second heat source 108b. Also, as illustrated in FIG. 9, the main heat transfer portion 112i and the main heat transfer portion 112j can both be connected or coupled to the reservoir portion 114h. The reservoir portion 114h can be located on a side or end of the main heat transfer portion 112i and the main heat transfer portion 112j and have a width that is wider than both a width of the main heat transfer portion 112i and/or the main heat transfer portion 112j. The reservoir portion 114h can be located on the heated end of the heat pipe with a liquid reservoir 104h, or the end of the heat pipe with a liquid reservoir 104h that is proximate to the first heat source 108a and the second heat source 108b. At least a majority of the reservoir portion 114h can include the wick material 116. The wick material 116 in the reservoir portion 114h can hold surplus liquid to be used when needed to help extend the time to dry out of the main heat transfer portion 112i and the main heat transfer portion 112j and/or if the first heat source 108a and/or the second heat source 108b are processors, the amount of time that can be spend using an increased clock frequency of the processor.

The main heat transfer portion 112i and the main heat transfer portion 112j each include the wick material 116 and the vapor channel 118. The amount of the wick material 116 in the main heat transfer portion 112i and the main heat transfer portion 112j is less than the amount of the wick material 116 in the reservoir portion 114h to allow vapor to flow through the vapor channel 118 towards the heatsink 106 (not shown).

The wick material 116 in the main heat transfer portion 112g can occupy between about thirty percent (30%) of the volume of the main heat transfer portion 112i to about sixty-five (65%) of the volume of the main heat transfer portion 112i and ranges therein (e.g., between about forty percent (40%) and about fifty (50%) of the volume of the main heat transfer portion 112g, or between about forty-five percent (45%) and about sixty (60%) of the volume of the main heat transfer portion 112i), depending on design choice, design constraints, and that amount the wick material 116 in the main heat transfer portion 112i allows for the vapor channel 118 and is less than the amount of wick in the reservoir portion 114h. The wick material 116 in the main heat transfer portion 112j can occupy between about thirty percent (30%) of the volume of the main heat transfer portion 112j to about sixty-five (65%) of the volume of the main heat transfer portion 112j and ranges therein (e.g., between about forty percent (40%) and about fifty (50%) of the volume of the main heat transfer portion 112j, or between about forty-five percent (45%) and about sixty (60%) of the volume of the main heat transfer portion 112j), depending on design choice, design constraints, and that amount the wick material 116 in the main heat transfer portion 112j allows for the vapor channel 118 and is less than the amount of wick in the reservoir portion 114h. The amount of the wick material 116 in the main heat transfer portion 112i and in the main heat transfer portion 112i does not need to be the same amount of wick material 116. The wick material 116 in the reservoir portion 114h does not need to be the same type as the wick material 116 in the main heat transfer portion 112i or the main heat transfer portion 122j. The amount of wick material 116 in the reservoir portion 114h is greater than the amount of the wick material 116 in the main heat transfer portion 112i and the main heat transfer portion 112j. More specifically, the wick material 116 in the reservoir portion 114h can occupy between about sixty-five percent (65%) of the volume in the reservoir portion 114h to about one-hundred percent (100%) of the volume in the reservoir portion 114h and ranges therein (e.g., between about seventy-five percent (75%) and about ninety-five percent (95%) of the volume in the reservoir portion 114h, or between about eighty percent (80%) and about ninety percent (90%) of the volume in the reservoir portion 114h), depending on design choice, design constraints, and that the amount of wick material 116 in the reservoir portion 114h is greater than the amount of wick in the main heat transfer portion 112i and the main heat transfer portion 112j. In some examples, the amount of the wick material 116 in the reservoir portion 114h is fifteen percent (15%) or more (e.g., twenty percent (20%), twenty-five percent (25%), thirty percent (30%), etc.) than the amount of the wick material 116 in the main heat transfer portion 112i or the main heat transfer portion 112j. More specifically, if the amount of the wick material 116 in the main heat transfer portion 112i is about fifty percent (50%) of the volume of the main heat transfer portion 112i or the amount of the wick material 116 in the main heat transfer portion 112j is about fifty percent (50%) of the volume of the main heat transfer portion 112j, then the amount of the wick material 116 in the reservoir portion 114h would be about sixty-five percent (65%) or more of the volume of the reservoir portion 114h.

The main heat transfer portion 112i and the main heat transfer portion 112j are each filled with a fluid held by the wick material 116 and by vapor occupying the vapor channel 118. Heat from the first heat source 108a and/or the second heat source 108b causes the liquid in the wick material 116 to vaporize. The vapor travels along the vapor channel 118 to the heatsink 106 (not shown) or the cold end of the main heat transfer portion 112i and the main heat transfer portion 112j and condenses into the wick material 116. The capillary force in the wick material 116 pulls the liquid back to the portion of the main heat transfer portion 112i and the main heat transfer portion 112j over the first heat source 108a and the second heat source 108b, thus completing the vapor-liquid flow loop. There is a maximum capillary pressure the wick material 116 can provide, defined by its porous structure. The presence of a maximum capillary pressure limits the amount of liquid that can be pulled from the cold end of the main heat transfer portion 112i and the main heat transfer portion 112j to the hot end of the main heat transfer portion 112i and the main heat transfer portion 112j. The reservoir portion 114h allows the heat pipe with a liquid reservoir 104h to hold surplus liquid to be used when needed to help extend the time to dry out of the main heat transfer portion 112i and the main heat transfer portion 112j and/or if the first heat source 108a and/or 108b are a processor, the amount of time that can be spend using an increased clock frequency of the processor. This surplus liquid will allow the heat pipe with a liquid reservoir 104h to sustain a high-power burst at powers greater than the Qₘₐₓ of the main heat transfer portion 112i and/or the main heat transfer portion 112j without drying out during the bust period.

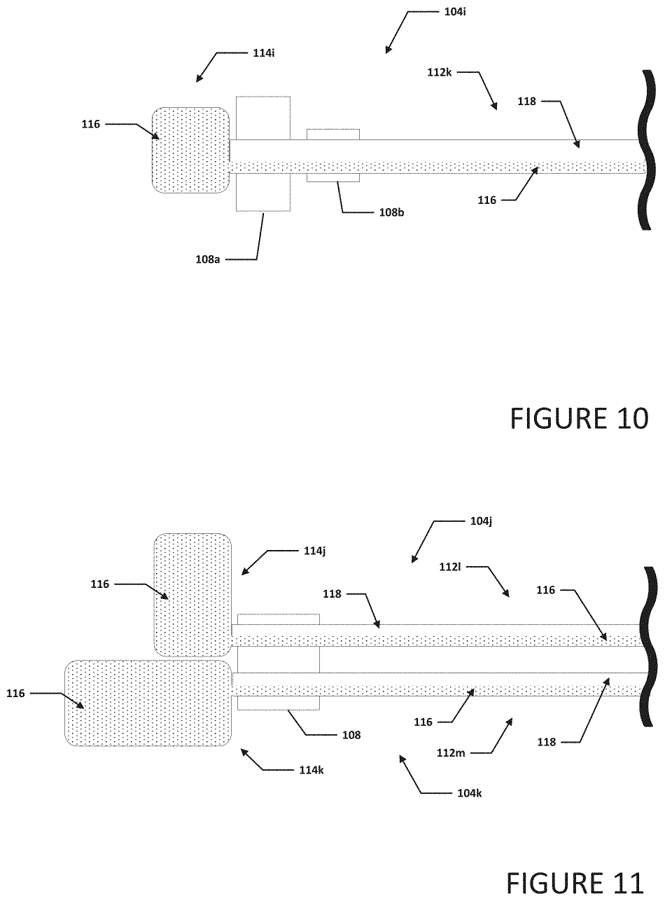

Turning to FIG. 10, FIG. 10 is a simplified block diagram of a portion of a heat pipe with a liquid reservoir 104i, in accordance with an embodiment of the present disclosure. In an example, the heat pipe with a liquid reservoir 104i can include a main heat transfer portion 112k, and a reservoir portion 114i. The heat pipe with a liquid reservoir 104i can be over one or more heat sources. For example, as illustrated in FIG. 10, the heat pipe with a liquid reservoir 104i can be over the first heat source 108a and the second heat source 108b. Also, as illustrated in FIG. 10, the main heat transfer portion 112k can be connected or coupled to the reservoir portion 114i. The reservoir portion 114i can be located on the heated end of the heat pipe with a liquid reservoir 104i, or the end of the heat pipe with a liquid reservoir 104i that is proximate to the first heat source 108a and the second heat source 108b and have a width that is wider than a width of the main heat transfer portion 112k. At least a majority of the reservoir portion 114i can include the wick material 116. The wick material 116 in the reservoir portion 114i can hold surplus liquid to be used when needed to help extend the time to dry out of the main heat transfer portion 112k and/or if the first heat source 108a and/or the second heat source 108b are a processor, the amount of time that can be spend using an increased clock frequency of the processor. The main heat transfer portion 112k can include the wick material 116 and the vapor channel 118. The amount of the wick material 116 in the main heat transfer portion 112k is less than the amount of the wick material 116 in the reservoir portion 114i to allow vapor to flow through the vapor channel 118 towards the heatsink 106 (not shown). The main heat transfer portion 112k can be filled with a fluid held by the wick material 116 and vapor occupying the vapor channel 118.

The wick material 116 in the main heat transfer portion 112k can occupy between about thirty percent (30%) of the volume of the main heat transfer portion 112k to about sixty-five (65%) of the volume of the main heat transfer portion 112i and ranges therein (e.g., between about forty percent (40%) and about fifty (50%) of the volume of the main heat transfer portion 112g, or between about forty-five percent (45%) and about sixty (60%) of the volume of the main heat transfer portion 112k), depending on design choice, design constraints, and that amount the wick material 116 in the main heat transfer portion 112k allows for the vapor channel 118 and is less than the amount of wick in the reservoir portion 114i. The wick material 116 in the reservoir portion 114i does not need to be the same type as the wick material 116 in the main heat transfer portion 112k. The amount of wick material 116 in the reservoir portion 114i is greater than the amount of the wick material 116 in the main heat transfer portion 112k. More specifically, the wick material 116 in the reservoir portion 114i can occupy between about sixty-five percent (65%) of the volume in the reservoir portion 114i to about one-hundred percent (100%) of the volume in the reservoir portion 114i and ranges therein (e.g., between about seventy-five percent (75%) and about ninety-five percent (95%) of the volume in the reservoir portion 114i, or between about eighty percent (80%) and about ninety percent (90%) of the volume in the reservoir portion 114i), depending on design choice, design constraints, and that the amount of wick material 116 in the reservoir portion 114i is greater than the amount of wick in the main heat transfer portion 112k. In some examples, the amount of the wick material 116 in the reservoir portion 114i is fifteen percent (15%) or more (e.g., twenty percent (20%), twenty-five percent (25%), thirty percent (30%), etc.) than the amount of the wick material 116 in the main heat transfer portion 112k. More specifically, if the amount of the wick material 116 in the main heat transfer portion 112k is about fifty percent (50%) of the volume of the main heat transfer portion 112k, then the amount of the wick material 116 in the reservoir portion 114i would be about sixty-five percent (65%) or more of the volume of the reservoir portion 114i.

Heat from the first heat source 108a and/or the second heat source 108b causes the liquid in the wick material 116 to vaporize. The vapor travels along the vapor channel 118 to the heatsink 106 (not shown) or the cold end of the main heat transfer portion 112k and condenses into the wick material 116. The capillary force in the wick material 116 pulls the liquid back to the portion of the main heat transfer portion 112k over the first heat source 108a and the second heat source 108b, thus completing the vapor-liquid flow loop. There is a maximum capillary pressure the wick material 116 can provide, defined by its porous structure. The presence of a maximum capillary pressure limits the amount of liquid that can be pulled from the cold end of the main heat transfer portion 112k to the hot end of the main heat transfer portion 112k. The reservoir portion 114i allows the heat pipe with a liquid reservoir 104i to hold surplus liquid to be used when needed to help extend the time to dry out of the main heat transfer portion 112k and/or if the first heat source 108a and/or the second heat source 108b are a processor, the amount of time that can be spend using an increased clock frequency of the processor. This surplus liquid will allow the heat pipe with a liquid reservoir 104i to sustain a high-power burst at powers greater than the Qₘₐₓ of the main heat transfer portion 112k without drying out during the burst period.

Turning to FIG. 11, FIG. 11 is a simplified diagram of is a simplified block diagram of a portion of a heat pipe with a liquid reservoir 104j and a portion of a heat pipe with a liquid reservoir 104k over the heat source 108, in accordance with an embodiment of the present disclosure. In an example, the heat pipe with a liquid reservoir 104j can include a main heat transfer portion 112l and a reservoir portion 114j and the heat pipe with a liquid reservoir 104k can include a main heat transfer portion 112k and a reservoir portion 114k. For example, as illustrated in FIG. 11, the main heat transfer portion 112l can be connected or coupled to the reservoir portion 114j and the main heat transfer portion 112m can be connected or coupled to the reservoir portion 114k. The reservoir portion 114j can be located on a side or end of the main heat transfer portion 112l and have a width that is wider than a width of the main heat transfer portion 112l and the reservoir portion 114k can be located on a side or end of the main heat transfer portion 112m and have a width that is wider than a width of the main heat transfer portion 112m. The reservoir portion 114j can be located on the heated end of the heat pipe with a liquid reservoir 104j, or the end of the heat pipe with a liquid reservoir 104j that is proximate to the heat source 108 and the reservoir portion 114k can be located on the heated end of the heat pipe with a liquid reservoir 104k, or the end of the heat pipe with a liquid reservoir 104k that is proximate to the heat source 108.

At least a majority of the reservoir portion 114j can include the wick material 116. The wick material 116 in the reservoir portion 114j can hold surplus liquid to be used when needed to help extend the time to dry out of the main heat transfer portion 112l and/or if the heat source 108 is a processor, the amount of time that can be spend using an increased clock frequency of the processor. In addition, at least a majority of the reservoir portion 114k can include the wick material 116. The wick material 116 in the reservoir portion 114k can hold surplus liquid to be used when needed to help extend the time to dry out of the main heat transfer portion 112m and/or if heat source 108 is a processor, the amount of time that can be spend using an increased clock frequency of the processor.

The main heat transfer portion 112l can include the wick material 116 and the vapor channel 118. The amount of the wick material 116 in the main heat transfer portion 112l is less than the amount of the wick material 116 in the reservoir portion 114j to allow vapor to flow through the vapor channel 118 towards the heatsink 106 (not shown). The main heat transfer portion 112j can be filled with a fluid held by the wick material 116 and vapor occupying the vapor channel 118. Also, the main heat transfer portion 112m can include the wick material 116 and the vapor channel 118. The amount in the wick material 116 in the main heat transfer portion 112m is less than the amount of the wick material 116 in the reservoir portion 114k to allow vapor to flow through the vapor channel 118 towards the heatsink 106 (not shown). The main heat transfer portion 112m can be filled with a fluid held by the wick material 116 and vapor occupying the vapor channel 118.

The wick material 116 in the main heat transfer portion 112l can occupy between about thirty percent (30%) of the volume of the main heat transfer portion 112l to about sixty-five (65%) of the volume of the main heat transfer portion 112i and ranges therein (e.g., between about forty percent (40%) and about fifty (50%) of the volume of the main heat transfer portion 112g, or between about forty-five percent (45%) and about sixty (60%) of the volume of the main heat transfer portion 112l), depending on design choice, design constraints, and that amount the wick material 116 in the main heat transfer portion 112l allows for the vapor channel 118 and is less than the amount of wick in the reservoir portion 114j. The amount of wick material 116 in the reservoir portion 114j is greater than the amount of the wick material 116 in the main heat transfer portion 112l. More specifically, the wick material 116 in the reservoir portion 114j can occupy between about sixty-five percent (65%) of the volume in the reservoir portion 114j to about one-hundred percent (100%) of the volume in the reservoir portion 114j and ranges therein (e.g., between about seventy-five percent (75%) and about ninety-five percent (95%) of the volume in the reservoir portion 114j, or between about eighty percent (80%) and about ninety percent (90%) of the volume in the reservoir portion 114j), depending on design choice, design constraints, and that the amount of wick material 116 in the reservoir portion 114j is greater than the amount of wick in the main heat transfer portion 112l. In some examples, the amount of the wick material 116 in the reservoir portion 114j is fifteen percent (15%) or more (e.g., twenty percent (20%), twenty-five percent (25%), thirty percent (30%), etc.) than the amount of the wick material 116 in the main heat transfer portion 112l. More specifically, if the amount of the wick material 116 in the main heat transfer portion 112l is about fifty percent (50%) of the volume of the main heat transfer portion 112l, then the amount of the wick material 116 in the reservoir portion 114j would be about sixty-five percent (65%) or more of the volume of the reservoir portion 114j.

The wick material 116 in the main heat transfer portion 112m can occupy between about thirty percent (30%) of the volume of the main heat transfer portion 112m to about sixty-five (65%) of the volume of the main heat transfer portion 112m and ranges therein (e.g., between about forty percent (40%) and about fifty (50%) of the volume of the main heat transfer portion 112m, or between about forty-five percent (45%) and about sixty (60%) of the volume of the main heat transfer portion 112m), depending on design choice, design constraints, and that amount the wick material 116 in the main heat transfer portion 112m allows for the vapor channel 118 and is less than the amount of wick in the reservoir portion 114k. The amount of wick material 116 in the reservoir portion 114k is greater than the amount of the wick material 116 in the main heat transfer portion 112m. More specifically, the wick material 116 in the reservoir portion 114k can occupy between about sixty-five percent (65%) of the volume in the reservoir portion 114k to about one-hundred percent (100%) of the volume in the reservoir portion 114k and ranges therein (e.g., between about seventy-five percent (75%) and about ninety-five percent (95%) of the volume in the reservoir portion 114k, or between about eighty percent (80%) and about ninety percent (90%) of the volume in the reservoir portion 114k), depending on design choice, design constraints, and that the amount of wick material 116 in the reservoir portion 114k is greater than the amount of wick in the main heat transfer portion 112l. In some examples, the amount of the wick material 116 in the reservoir portion 114k is fifteen percent (15%) or more (e.g., twenty percent (20%), twenty-five percent (25%), thirty percent (30%), etc.) than the amount of the wick material 116 in the main heat transfer portion 112m. More specifically, if the amount of the wick material 116 in the main heat transfer portion 112m is about fifty percent (50%) of the volume of the main heat transfer portion 112m, then the amount of the wick material 116 in the reservoir portion 114k would be about sixty-five percent (65%) or more of the volume of the reservoir portion 114k.

The amount of the wick material 116 in the main heat transfer portion 112l and the main heat transfer portion 112m does not need to be the same. The amount of the wick material 116 in the reservoir portion 114j and the reservoir portion 114k does not need to be the same amount of wick material 116. The type of the wick material 116 in the main heat transfer portion 112l, the main heat transfer portion 112m, the reservoir portion 114j, and/or the reservoir portion 114k does not need to be the same.

Heat from the heat source 108 causes the liquid in the wick material 116 in the main heat transfer portion 112l and in the wick material 116 in the main heat transfer portion 112m to vaporize. The vapor travels along the vapor channel 118 to the heatsink 106 (not shown) or the cold end of the main heat transfer portion 112l and/or the main heat transfer portion 112m and condenses into the wick material 116. The capillary force in the wick material 116 pulls the liquid back to the portion of the main heat transfer portion 112l and/or the main heat transfer portion 112m over the heat source 108, thus completing the vapor-liquid flow loop. There is a maximum capillary pressure the wick material 116 can provide, defined by its porous structure. The presence of a maximum capillary pressure limits the amount of liquid that can be pulled from the cold end of the main heat transfer portion 112l and/or the main heat transfer portion 112m to the hot end of the main heat transfer portion 112l and/or the main heat transfer portion 112m. The reservoir portion 114j allows the heat pipe with a liquid reservoir 104j to hold surplus liquid to be used when needed to help extend the time to dry out of the main heat transfer portion 112l and/or if the heat source 108 is a processor, the amount of time that can be spend using an increased clock frequency of the processor. This surplus liquid will allow the heat pipe with a liquid reservoir 104j to sustain a high-power burst at powers greater than the Qₘₐₓ of the main heat transfer portion 112l without drying out during the burst period. In addition, the reservoir portion 114k allows the heat pipe with a liquid reservoir 104k to hold surplus liquid to be used when needed to help extend the time to dry out of the main heat transfer portion 112m and/or if the heat source 108 is a processor, the amount of time that can be spend using an increased clock frequency of the processor. This surplus liquid will allow the heat pipe with a liquid reservoir 104k to sustain a high-power burst at powers greater than the Qₘₐₓ of the main heat transfer portion 112m without drying out during the burst period.

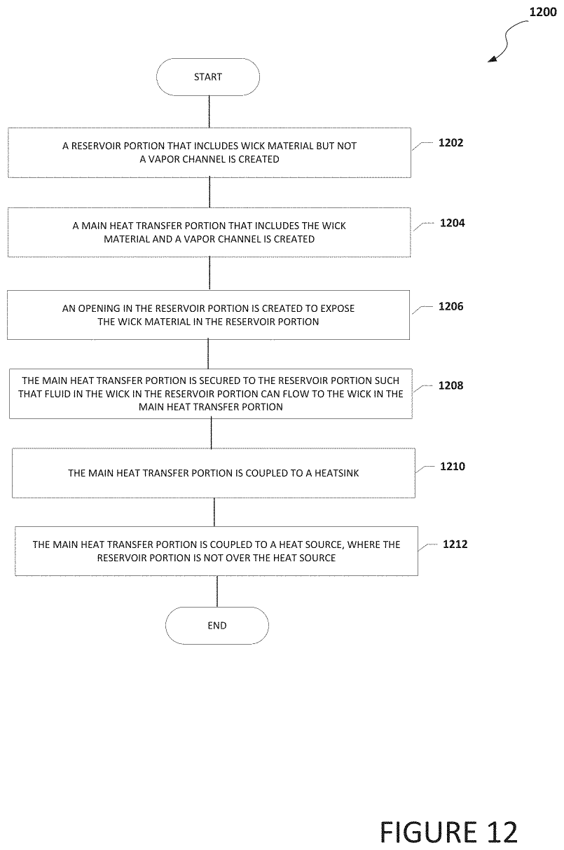

Turning to FIG. 12, FIG. 12 is an example flowchart illustrating possible operations of a flow 1200 that may be associated with creating a heat pip with a liquid reservoir, in accordance with an embodiment. At 1202, a reservoir portion that includes wick material but not a vapor channel is created. For example, a reservoir portion can be created where the reservoir portion includes enough wick that there is not room for a vapor channel. At 1204, a main heat transfer portion that includes the wick material and a vapor channel is created. At 1206, an opening in the reservoir portion is created to expose the wick material in the reservoir portion. At 1208, the main heat transfer portion is secured to the reservoir portion such that fluid in the wick in the reservoir portion can flow to the wick in the main heat transfer portion. This creates a heat pipe with a liquid reservoir. At 1210, the main heat transfer portion is coupled to a heatsink. At 1212, the main heat transfer portion is coupled to a heat source such that the reservoir portion is not over the heat source.

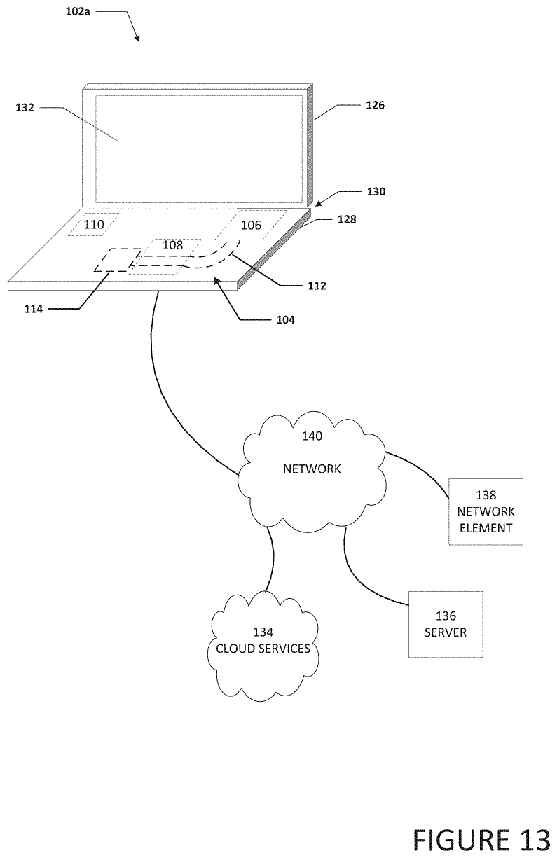

Turning to FIG. 13, FIG. 13 is a simplified block diagram of an electronic device 102a configured with the heat pipe with a liquid reservoir 104, in accordance with an embodiment of the present disclosure. In an example, the electronic device 102a can include a first housing 126 and a second housing 128. The first housing 126 and the second housing 128 can be rotatably or pivotably coupled together using a hinge 130. The first housing 126 can include a display 132. The second housing 128 can include the heat pipe with a liquid reservoir 104, one or more heatsinks 106, one or more heat sources 108, and one or more electronic components 110.

Each of one or more heat sources 108 may be a heat generating device (e.g., processor, logic unit, field programmable gate array (FPGA), chip set, integrated circuit (IC), a graphics processor, graphics card, battery, memory, or some other type of heat generating device). The heat pipe with a liquid reservoir 104 is configured to help cool one or more heat sources 108 and transfer the heat from the heat source 108 to the heatsink 106. The heatsink 106 is configured to help transfer the heat collected by the heat pipe with a liquid reservoir 104 away from the electronic device 102a (e.g., to the environment around the electronic device 102a). The heatsink 106 may be a passive cooling device or an active cooling device to help reduce the thermal energy or temperature of one or more heat sources 108. In an example, heatsink 106 can draw air into the second housing 128 though one or more inlet vents in the housing or chassis of the electronic device 102a and use the air to help dissipate the heat collected by the heat pipe with a liquid reservoir 104.

Implementations of the embodiments disclosed herein may be formed or carried out on a substrate, such as a non-semiconductor substrate or a semiconductor substrate. In one implementation, the non-semiconductor substrate may be silicon dioxide, an inter-layer dielectric composed of silicon dioxide, silicon nitride, titanium oxide and other transition metal oxides. Although a few examples of materials from which the non-semiconducting substrate may be formed are described here, any material that may serve as a foundation upon which a non-semiconductor device may be built falls within the spirit and scope of the embodiments disclosed herein.

In another implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. In other examples, the substrate may be a flexible substrate including 2D materials such as graphene and molybdenum disulphide, organic materials such as pentacene, transparent oxides such as indium gallium zinc oxide poly/amorphous (low temperature of dep) III-V semiconductors and germanium/silicon, and other non-silicon flexible substrates. Although a few examples of materials from which the substrate may be formed are described here, any material that may serve as a foundation upon which a semiconductor device may be built falls within the spirit and scope of the embodiments disclosed herein.

The electronic device 102a (and the electronic device 102) may be in communication with cloud services 134, one or more servers 136, and/or one or more network elements 138 using a network 140. In some examples, the electronic device 102a (and the electronic device 102) may be standalone devices and not connected to the network 140 or another device

Elements of FIG. 13 may be coupled to one another through one or more interfaces employing any suitable connections (wired or wireless), which provide viable pathways for network (e.g., the network 140, etc.) communications. Additionally, any one or more of these elements of FIG. 13 may be combined or removed from the architecture based on particular configuration needs. The network 140 may include a configuration capable of transmission control protocol/Internet protocol (TCP/IP) communications for the transmission or reception of packets in a network. The electronic device 102a (and the electronic device 102) may also operate in conjunction with a user datagram protocol/IP (UDP/IP) or any other suitable protocol where appropriate and based on particular needs.

Turning to the infrastructure of FIG. 13, the network 140 represents a series of points or nodes of interconnected communication paths for receiving and transmitting packets of information. The network 140 offers a communicative interface between nodes, and may be configured as any local area network (LAN), virtual local area network (VLAN), wide area network (WAN), wireless local area network (WLAN), metropolitan area network (MAN), Intranet, Extranet, virtual private network (VPN), and any other appropriate architecture or system that facilitates communications in a network environment, or any suitable combination thereof, including wired and/or wireless communication.

In the network 140, network traffic, which is inclusive of packets, frames, signals, data, etc., can be sent and received according to any suitable communication messaging protocols. Suitable communication messaging protocols can include a multi-layered scheme such as Open Systems Interconnection (OSI) model, or any derivations or variants thereof (e.g., Transmission Control Protocol/Internet Protocol (TCP/IP), user datagram protocol/IP (UDP/IP)). Messages through the network could be made in accordance with various network protocols, (e.g., Ethernet, Infiniband, OmniPath, etc.). Additionally, radio signal communications over a cellular network may also be provided. Suitable interfaces and infrastructure may be provided to enable communication with the cellular network.

The term “packet” as used herein, refers to a unit of data that can be routed between a source node and a destination node on a packet switched network. A packet includes a source network address and a destination network address. These network addresses can be Internet Protocol (IP) addresses in a TCP/IP messaging protocol. The term “data” as used herein, refers to any type of binary, numeric, voice, video, textual, or script data, or any type of source or object code, or any other suitable information in any appropriate format that may be communicated from one point to another in electronic devices and/or networks.

Although the present disclosure has been described in detail with reference to particular arrangements and configurations, these example configurations and arrangements may be changed significantly without departing from the scope of the present disclosure. Moreover, certain components may be combined, separated, eliminated, or added based on particular needs and implementations. Additionally, although the heat pipe with a liquid reservoir 104 and 104a-104k have been illustrated with reference to particular elements and operations, these elements and operations may be replaced by any suitable architecture, protocols, and/or processes that achieve the intended functionality of the heat pipe with a liquid reservoir 104 and 104a-104k.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 112 as it exists on the date of the filing hereof unless the words “means for” or “step for” are specifically used in the particular claims; and (b) does not intend, by any statement in the specification, to limit this disclosure in any way that is not otherwise reflected in the appended claims.

### Other Notes and Examples

In Example A1, an electronic device can include a main heat transfer portion that includes wick material and a vapor channel and a reservoir portion that includes the wick material. The wick material in the reservoir portion occupies at least about fifteen percent more of a volume of the reservoir portion than a percentage of a volume that the wick material occupies in the main heat transfer portion.

In Example A2, the subject matter of Example A1 can optionally include where the reservoir portion includes a fluid that is converted to vapor when the main heat transfer portion starts to experience dryout.

In Example A3, the subject matter of any one of Examples A1-A2 can optionally include where a rate of vaporization of the fluid matches a maximum liquid flow rate of the fluid through the wick material in the main heat transfer portion.

In Example A4, the subject matter of any one of Examples A1-A3 can optionally include where when a Qmax of the fluid is reach, the fluid from the reservoir portion flows into the wick in the main heat transfer portion and begins to vaporize.

In Example A5, the subject matter of any one of Examples A1-A4 can optionally include where the main heat transfer portion is over at least one heat source and the reservoir portion is not over the at least one heat source.

In Example A6, the subject matter of any one of Examples A1-A5 can optionally include where the reservoir portion has a height that is greater than a height of the main heat transfer portion.

In Example A7, the subject matter of any one of Examples A1-A6 can optionally include where the main heat transfer portion is coupled to a heatsink.

Example M1 is a method including creating a main heat transfer portion that includes wick material and a vapor channel, creating a reservoir portion that includes the wick material but not the vapor channel, creating an opening in the reservoir portion and exposing the wick material in the reservoir portion, and securing the main heat transfer portion to the reservoir portion such that fluid in the wick material of the reservoir portion can flow to the wick material in the main heat transfer portion.

In Example M2, the subject matter of Example M1 can optionally include where the reservoir portion holds surplus liquid that is used when the main heat transfer portion starts to experience dryout.

In Example M3, the subject matter of any one of the Examples M1-M2 can optionally include where the wick material in the reservoir portion occupies at least about fifteen percent more of a volume of the reservoir portion than a percentage of a volume that the wick material occupies in the main heat transfer portion.

In Example M4, the subject matter of any one of the Examples M1-M3 can optionally include where the reservoir portion has a height that is greater than a height of the main heat transfer portion and a width that is wider than the main heat transfer portion.

In Example M5, the subject matter of any one of the Examples M1-M4 can optionally include coupling the main heat transfer portion to a heatsink.

In Example, M6, the subject matter of any one of the Examples M1-M5 can optionally include coupling the main heat transfer portion to a heat source, where the reservoir portion is not over the heat source.

Example AA1 is a device including one or more heat sources, a heatsink, and a heat pipe. The heat pipe can include a main heat transfer portion that includes wick material and a vapor channel that extends to the heatsink, a reservoir portion that includes the wick material, where the wick material in the reservoir portion occupies between about sixty-five percent (65%) of a volume of the reservoir portion to about one-hundred percent (100%) of the volume of the reservoir portion, and a fluid, where the fluid is a liquid in the wick material and a vapor in the vapor channel.

In Example AA2, the subject matter of Example AA1 can optionally include where the wick material in main heat transfer portion can occupy between about thirty percent of a volume in the main heat transfer portion to about sixty-five of the volume in the main heat transfer portion.

In Example AA3, the subject matter of any one of Examples AA1-AA2 can optionally include where the wick material in the reservoir portion occupies at least about fifteen percent more of the volume of the reservoir portion than a percentage of the volume that the wick material occupies in the main heat transfer portion.

In Example AA4, the subject matter of any one of Examples AA1-AA3 can optionally include where the fluid has a Qmax where a rate of vaporization of the fluid matches a maximum liquid flow rate of the fluid through the wick material and when Qmax is reach, fluid from the reservoir portion begins to vaporize.

In Example AA5, the subject matter of any one of Examples AA1-AA4 can optionally include where the main heat transfer portion is over at least one heat source and the reservoir portion is not over the at least one heat source.

In Example AA6, the subject matter of any one of Examples AA1-AA5 can optionally include where the reservoir portion does not include the vapor channel.

In Example AA7, the subject matter of any one of Examples AA1-AA6 can optionally include where the reservoir portion has a circular profile.

What is claimed is:

1. A heat pipe comprising:
a main heat transfer portion that includes wick material and a vapor channel; and
a reservoir portion that includes the wick material, wherein the wick material in the reservoir portion occupies at least about fifteen percent more of a volume of the reservoir portion than a percentage of a volume that the wick material occupies in the main heat transfer portion.

2. The heat pipe of claim 1, wherein the reservoir portion includes a fluid that is converted to vapor when the main heat transfer portion starts to experience dryout.

3. The heat pipe of claim 2, wherein a rate of vaporization of the fluid matches a maximum liquid flow rate of the fluid through the wick material in the main heat transfer portion.

4. The heat pipe of claim 2, wherein when a Qmax of the fluid is reach, the fluid from the reservoir portion flows into the wick material in the main heat transfer portion and begins to vaporize.

5. The heat pipe of claim 1, wherein the main heat transfer portion is over at least one heat source and the reservoir portion is not over the at least one heat source.

6. The heat pipe of claim 1, wherein the reservoir portion has a height that is greater than a height of the main heat transfer portion.

7. The heat pipe of claim 1, wherein the main heat transfer portion is coupled to a heatsink.

8. A device comprising:
one or more heat sources;
a heatsink; and
a heat pipe, wherein the heat pipe include:
a main heat transfer portion that includes wick material and a vapor channel that extends to the heatsink;
a reservoir portion that includes the wick material, wherein the wick material in the reservoir portion occupies between about sixty-five percent of a volume of the reservoir portion to about one-hundred percent of the volume of the reservoir portion; and
a fluid, wherein the fluid is a liquid in the wick material and a vapor in the vapor channel.

9. The device of claim 8, wherein the wick material in main heat transfer portion can occupy between about thirty percent of a volume in the main heat transfer portion to about sixty-five of the volume in the main heat transfer portion.

10. The device of claim 8, wherein the wick material in the reservoir portion occupies at least about fifteen percent more of the volume of the reservoir portion than a percentage of the volume that the wick material occupies in the main heat transfer portion.

11. The device of claim 8, wherein the fluid has a Qmax where a rate of vaporization of the fluid matches a maximum liquid flow rate of the fluid through the wick material and when Qmax is reach, fluid from the reservoir portion begins to vaporize.

12. The device of claim 8, wherein the main heat transfer portion is over at least one heat source and the reservoir portion is not over the at least one heat source.

13. The device of claim 8, wherein the reservoir portion does not include the vapor channel.

14. The device of claim 8, wherein the reservoir portion has a circular profile.

15. A method for creating a heat pipe with a liquid reservoir, the method comprising:
creating a main heat transfer portion that includes wick material and a vapor channel;
creating a reservoir portion that includes the wick material but not the vapor channel;
creating an opening in the reservoir portion and exposing the wick material in the reservoir portion; and
securing the main heat transfer portion to the reservoir portion such that fluid in the wick material of the reservoir portion can flow to the wick material in the main heat transfer portion.

16. The method of claim 15, wherein the reservoir portion holds surplus liquid that is used when the main heat transfer portion starts to experience dryout.

17. The method of claim 15, wherein the wick material in the reservoir portion occupies at least about fifteen percent more of a volume of the reservoir portion than a percentage of a volume that the wick material occupies in the main heat transfer portion.

18. The method of claim 15, wherein the reservoir portion has a height that is greater than a height of the main heat transfer portion and a width that is wider than the main heat transfer portion.

19. The method of claim 15, further comprising:
coupling the main heat transfer portion to a heatsink.

20. The method of claim 15, further comprising:
coupling the main heat transfer portion to a heat source, wherein the reservoir portion is not over the heat source.
